(19) United States
(12) Patent Application Publication
(10) Pub. No.: US 2025/0380064 A1
(43) Pub. Date: Dec. 11, 2025

(54) Image-sensing array with sparse autofocus pixels

(71) Applicant: APPLE INC., Cupertino, CA (US)

(72) Inventors: Xiangli Li, Palo Alto, CA (US); Gilad Michael, Sunnyvale, CA (US)

(21) Appl. No.: 19/050,163

(22) Filed: Feb. 11, 2025

Related U.S. Application Data
(60) Provisional application No. 63/657,871, filed on Jun. 9, 2024.

(51) Int. Cl. H04N 25/704; H04N 25/13

(52) U.S. Cl. CPC H04N 25/704; H04N 25/134

(57) ABSTRACT

An image sensing device includes a semiconductor substrate and a first array of photodetectors disposed on the substrate at a predefined pitch. A color filter layer is disposed over the photodetectors and includes a matrix of red, green, and blue regions, each region overlying a respective group of the photodetectors. A second array of microlenses is disposed over the color filter layer and includes first microlenses having a first transverse dimension no greater than the pitch disposed respectively over all the photodetectors within the green regions, and second microlenses having a second transverse dimension greater than the pitch disposed over at least some of the photodetectors within the red and blue regions. Each second microlens is configured to focus light onto two or more of the photodetectors in the respective group.

### CROSS-REFERENCE TO RELATED APPLICATION

This application claims the benefit of U.S. Provisional Patent Application 63/657,871, filed June 9, 2024, which is incorporated herein by reference.

### FIELD

The present invention relates generally to image sensing arrays and particularly to arrays including autofocus pixels and methods for their fabrication and use.

### BACKGROUND

Camera systems use autofocus (AF) in many applications to ensure that relevant portions of scenes, at varying distances from the camera, are acquired in sharp focus. Some autofocus systems use image information output by the image sensor of the camera in estimating the optimal distance of the image sensor from the camera lens. On- board electromechanical components then drive the lens position to the optimal distance from the image sensor.

To improve autofocus performance, some cameras use dual-pixel autofocus, and particularly phase difference- based autofocus, based on signals output by special pixels in the image sensing array that are divided into two sub- pixels. These special pixels can be created, for example, by fabricating a metal shield over certain pixels in such a way as to obscure one half of the sensing area of each such pixel. Phase-difference autofocus logic compares the outputs of the divided sub-pixels in order to estimate whether the image is in focus, and thus provides feedback in order to drive the lens to converge rapidly to a position at which the image is in focus.

U.S. Patent 11,563,910, whose disclosure is incorporated herein by reference, describes an image capture device including an array of pixels. Each pixel includes a 2×2 array of photodetectors. The image capture device also includes an array of 1×2 on-chip lenses (OCLs) disposed over the array of pixels, in a manner that is said to improve phase detection autofocus (PDAF).

In the present description and in the claims, the terms "light" and "optical radiation" are used interchangeably to refer to electromagnetic radiation in any of the visible, infrared, and ultraviolet spectral ranges.

### SUMMARY

Embodiments of the present invention that are described hereinbelow provide improved image sensing arrays and image capture devices.

There is therefore provided, in accordance with an embodiment of the invention, an image sensing device, including a semiconductor substrate and a first array of photodetectors disposed on the substrate at a predefined pitch. A color filter layer is disposed over the photodetectors and includes a matrix of red, green, and blue regions, each region overlying a respective group of the photodetectors. A second array of microlenses is disposed over the color filter layer and includes first microlenses having a first transverse dimension no greater than the pitch disposed respectively over all the photodetectors within the green regions and second microlenses having a second transverse dimension greater than the pitch disposed over at least some of the photodetectors within the red and blue regions. Each second microlens is configured to focus light onto two or more of the photodetectors in the respective group.

In some embodiments, the two or more of the photodetectors onto which the second microlenses focus the light define phase detection autofocus (PDAF) pixels.

There is also provided, in accordance with an embodiment of the invention, imaging apparatus, including the device described above and objective optics configured to image a target onto the device. An autofocus mechanism is configured to adjust a focal property of the objective optics. A controller is configured to drive the autofocus mechanism responsively to signals output by the PDAF pixels.

In a disclosed embodiment, the controller is further configured to reconstruct a full-color image based on signals output by the photodetectors by first computing a green image by interpolating the signals of the photodetectors in the green regions over the red and blue regions and then computing red and blue images by interpolating the signals of the photodetectors in the red and blue regions using the green image.

In some embodiments, the second transverse dimension is twice the pitch. In a disclosed embodiment, each of at least some of the second microlenses is configured to focus the light onto a respective 1x2 set of the photodetectors. In one embodiment, for some of the second microlenses, the respective 1x2 set of the photodetectors is disposed along a row of the array, while for others of the second microlenses, the respective 1x2 set of the photodetectors is disposed along a column of the array.

Alternatively, each of at least some of the second microlenses is configured to focus the light onto a respective 2x2 set of the photodetectors.

Further alternatively or additionally, the second microlenses are disposed over all the photodetectors within the red and blue regions.

In another embodiment, the second microlenses are disposed over only a first subset of the photodetectors within the red and blue regions, while the first microlenses are also disposed over a second subset of the photodetectors within the red and blue regions.

In a disclosed embodiment, the respective group of the photodetectors that is overlain by each of the red, green, and blue regions includes a 4x4 set of the photodetectors.

In yet another embodiment, within one or more of the red or blue regions, the color filter layer includes filters over some of the photodetectors of a color other than red or blue.

There is additionally provided, in accordance with an embodiment of the invention, a method for imaging, which includes providing a first array of photodetectors on a substrate at a predefined pitch and depositing over the photodetectors a color filter layer including a matrix of red, green, and blue regions, each region overlying a respective group of the photodetectors. Over the color filter layer, a second array of microlenses is formed including first microlenses having a first transverse dimension no greater than the pitch disposed respectively over all the photodetectors within the green regions, and second microlenses having a second transverse dimension greater than the pitch disposed over at least some of the photodetectors within the red and blue regions. Each second microlens being configured to focus light onto two or more of the photodetectors in the respective group.

### BRIEF DESCRIPTION OF THE DRAWINGS

The present invention will be more fully understood from the following detailed description of the embodiments thereof, taken together with the drawings in which:

FIG. 1 is a schematic side view of a camera comprising an image sensing device with sparse autofocus pixels, in accordance with an embodiment of the invention;

FIGS. 2, 3, 4A, 4B, 4C, 5, 6 and 7 are schematic partial frontal views of image sensing devices, in accordance with embodiments of the invention; and

FIG. 8 is a flow chart that schematically illustrates a method for processing a mosaic image output by an image sensing device, in accordance with an embodiment of the invention.

### DETAILED DESCRIPTION

Traditional Bayer-type color image sensors comprise an array of photodetectors overlaid with a color filter layer, comprising a matrix of red, green, and blue regions with the same pitch as the photodetector array, i.e., each color region in the matrix covers a single photodetector. For improved resolution and low-light performance (by binning together the signals from adjacent detectors), in some image sensors each colored region in the color filter layer overlies a group of four photodetectors. This sort of arrangement is described in the above-mentioned U.S. Patent 11,563,910. To increase resolution and performance still further, image sensors have been proposed in which each colored region in the color filter layer overlies a 4x4 set of the photodetectors, meaning a group of sixteen photodetectors. This sort of sensor enables both high resolution and high dynamic range, using either full resolution (no binning), 2x2 binning, or 4x4 binning depending on imaging conditions.

At the output from the camera, the mosaic of red, green, and blue raw color pixels is interpolated to reconstruct a full-color (RGB) image, with red, green, and blue intensity values for each pixel. Typically, the resolution of the RGB image depends mainly on the resolution of the green color channel. When PDAF pixels are included in the green regions of the image sensor, as in U.S. Patent 11,563,910, they can degrade the resolution in these regions, since the on-chip lenses (OCLs) introduce a small amount of local blur.

Embodiments of the present invention that are described herein remedy this problem by incorporating PDAF pixels only in the red and/or blue regions of the photodetector array. In these embodiments, an array of microlenses is disposed over the color filter layer of the image sensor. To achieve fine resolution, the microlenses disposed over all the photodetectors within the green regions have a transverse dimension no greater than the pitch of the photodetector array. (This sort of microlens is referred to as a "1x1 OCL," since there is one on-chip microlens for each photodetector.) In the red and/or blue regions, however, at least some of the microlenses have a transverse dimension greater than the pitch and thus focus light onto two or more of the photodetectors in the group that is overlain by the red or blue color filter. For example, either 1x2 or 2x2 OCLs, with a transverse dimension equal to twice the pitch of the photodetector array, may be used for this purpose in the red and/or blue regions.

The two or more photodetectors onto which each of these latter microlenses focuses light define a PDAF pixel, whose output signals can be used in focusing the camera in which the image sensing device is installed. All the microlenses in the red and/or blue regions may be of this type, or alternatively, some of the photodetectors in the red and/or blue regions may have 1x1 OCLs for enhanced resolution. In either case, full resolution is available in the green regions, while maintaining good autofocus performance regardless of the binning mode that may be applied. Limiting the distribution of PDAF pixels to certain areas of the photodetector array, such as to the red and blue regions, is referred to herein as a sparse distribution of the PDAF pixels.

Although the embodiments described herein are based specifically, for the sake of clarity and concreteness, on color matrices of red, green, and blue regions, with groups of sixteen photodetectors in each such region, the principles of the present invention may be applied to color filter layers including other colors, as well as to devices that provide larger or smaller numbers of photodetectors in each color region. For example, the features of the embodiments described below may be applied, mutatis mutandis, to the sort of image sensor described in the above-mentioned U.S. Patent 11,563,910, with four photodetectors in each region. As another example, the color filter arrays in the embodiments below may be modified to include clear (white) or gray regions. All such alternative implementations are considered to be within the scope of the present invention.

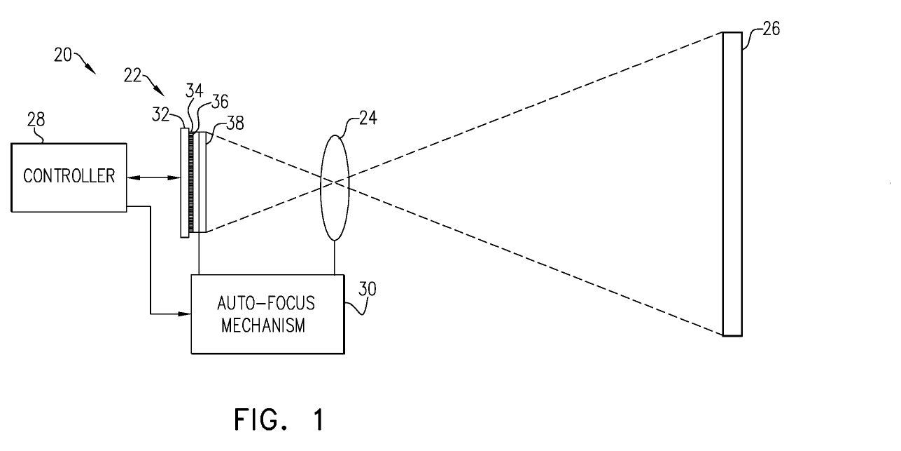

FIG. 1 is a schematic side view of a camera 20 comprising an image sensing device 22 with sparse PDAF pixels, in accordance with an embodiment of the invention. Objective optics 24 image a target 26 onto image sensing device 22. An autofocus mechanism 30 adjusts a focal property of the objective optics 24, for example by shifting the distance between optics 24 and device 22 or by adjusting the focal length of optics 24, as is known in the art. A controller 28 processes the signals output by the PDAF pixels and drives autofocus mechanism 30 in response to these signals so as to form a well-focused image on the image sensing device.

Image sensing device 22 comprises a semiconductor substrate 32, such as a silicon wafer substrate. An array of photodetectors 34, such as silicon photodiodes, is formed on substrate 32 at a predefined pitch, along with suitable switching and readout circuits (not shown in the figures). The photodetectors and associated circuits may be formed using any suitable process of thin film deposition and photolithography, such as a CMOS process. The circuits described in the above-mentioned U.S. Patent 11,563,910, for example, may be adapted for this purpose. A color filter layer 36 is deposited over photodetectors 34, and an array of microlenses 38 is disposed over color filter layer 36. Typically (although not necessarily), microlenses 38 comprise OCLs, which are also formed by a process of material deposition, photolithography, and etching, as is known in the art.

The figures that follow show various configurations of color filter layer 36 and microlenses 38 that may be used in accordance with embodiments of the invention. These figures show only partial views of the color filter matrix and corresponding microlenses, since the entire image sensing device, typically comprising many megapixels, cannot practically be shown in patent drawings.

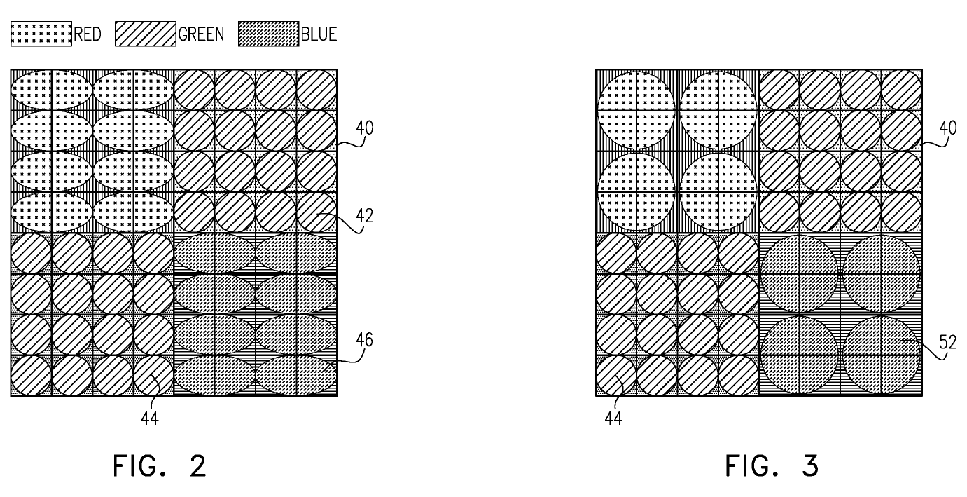

FIG. 2 is a schematic partial frontal view of image sensing device 22, in accordance with an embodiment of the invention. A color filter layer 40 comprises a matrix of red, green, and blue regions, each region overlying a respective 4x4 group of photodetectors 42. (The colors red, green, and blue are represented in FIG. 2 and in the drawings that follow by different hatch styles, as indicated in the legend above FIG. 2.) The pitch of the array of photodetectors 42 is equal to the distance between adjacent gridlines in this and subsequent figures. In the green regions of color filter layer 40, microlenses 44 comprise 1x1 OCLs, having a transverse dimension (diameter) that is equal to or slightly less than the pitch of photodetectors 42. In the red and blue regions, microlenses 46 comprise 1x2 OCLs, having a transverse dimension in the horizontal direction that is roughly twice the pitch of the photodetectors. Each microlens 46 focuses light onto a pair of adjacent photodetectors, which can then serve as a PDAF pixel.

The distribution of microlenses 44 and 46 in this embodiment enables the image sensing device to generate output images with resolution nearly as fine as that achieved when 1x1 OCLs are used over the entire array of photodetectors, while still achieving good autofocus performance. Although the 1x2 OCLs in this embodiment are oriented horizontally, along the rows of the photodetector array, in alternative embodiments, the 1x2 OCLs may be oriented vertically, along the columns of the array, or a mixture of horizontal and vertical OCLs may be used, as shown in the figures that follow. For even finer resolution, only a subset of the photodetectors in the red and/or blue regions of the color filter layer, may be configured as PDAF pixels, with 1x2 or 2x2 OCLs, for example, while the remaining subset of the photodetectors in the red and blue regions have 1x1 OCLs.

FIG. 3 is a schematic partial frontal view of image sensing device 22, in accordance with another embodiment of the invention. In this embodiment, as in the embodiment of FIG. 2, microlenses 44 in the green regions of color filter layer 40 comprise 1x1 OCLs. In the red and blue regions, however, microlenses 52 comprise 2x2 OCLs, having a transverse dimension in both the horizontal and vertical directions that is roughly twice the pitch of the photodetectors. Each microlens 52 focuses light onto a 2x2 group of adjacent photodetectors, which can then serve as a PDAF pixel. This embodiment may provide better autofocus performance at the expense of slightly reduced resolution.

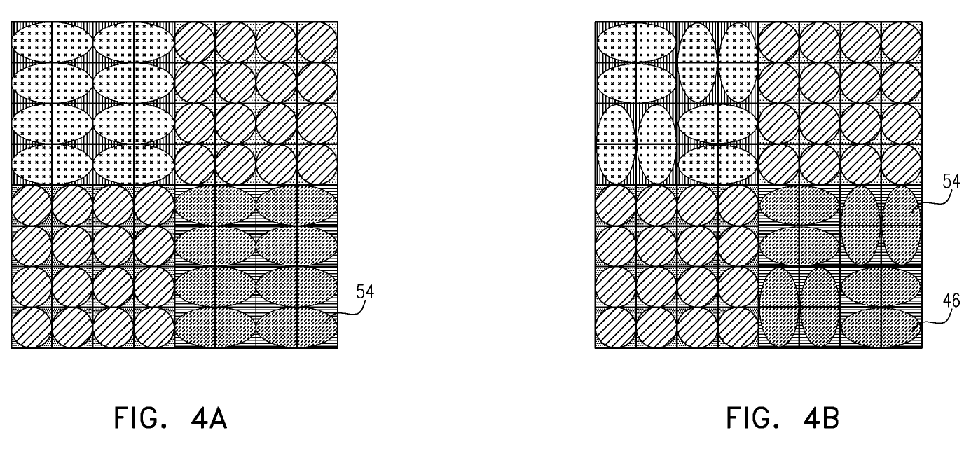

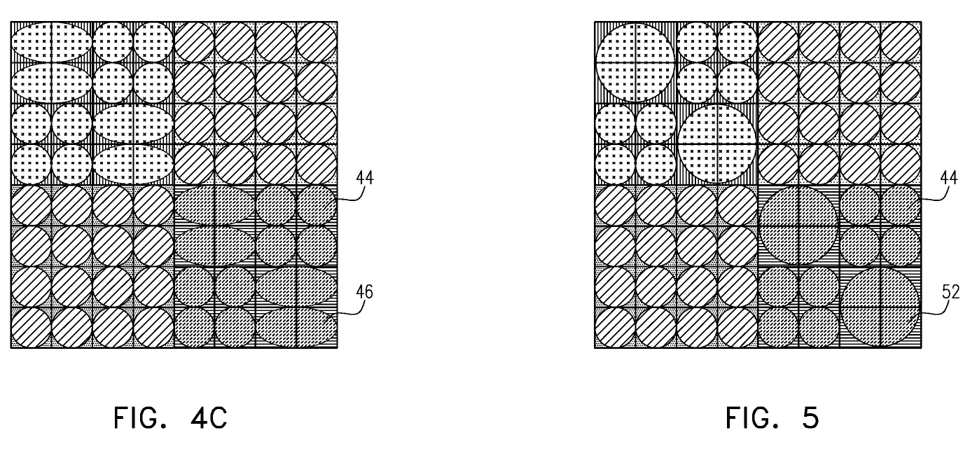

FIGS. 4A, 4B, and 4C are schematic partial frontal view of image sensing device 22, showing other possible distributions of 1x2 microlenses, in accordance with alternative embodiments of the invention. In the embodiment of FIG. 4A, microlenses 54 in the red and blue regions comprises 1x2 OCLs oriented vertically along the columns of the photodetector array. In FIG. 4B, the red and blue regions are covered by a mixture of microlenses 46 and 54. Microlenses 46 are oriented along the rows of the photodetector array, focusing light onto corresponding pairs of neighboring PDAF photodetector that are disposed along the rows; while microlenses 54 are oriented along the columns so that the corresponding pairs of neighboring PDAF photodetector are disposed along the columns. In FIG. 4C, the red and blue regions are covered partially by microlenses 44, which comprise 1x1 OCLs for high resolution, and partially by microlenses 46, comprising 1x2 OCLs for PDAF detection.

FIG. 5 is a schematic partial frontal view of image sensing device 22, in accordance with yet another embodiment of the invention. In this embodiment, the red and blue regions are covered partially by microlenses 44, comprising 1x1 OCLs for high resolution, and partially by microlenses 52, comprising 2x2 OCLs for PDAF detection.

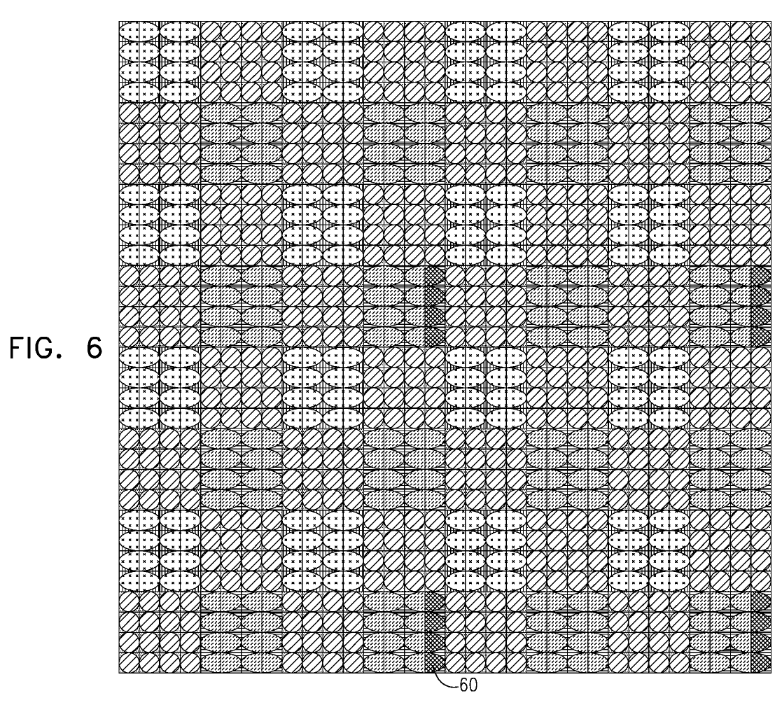

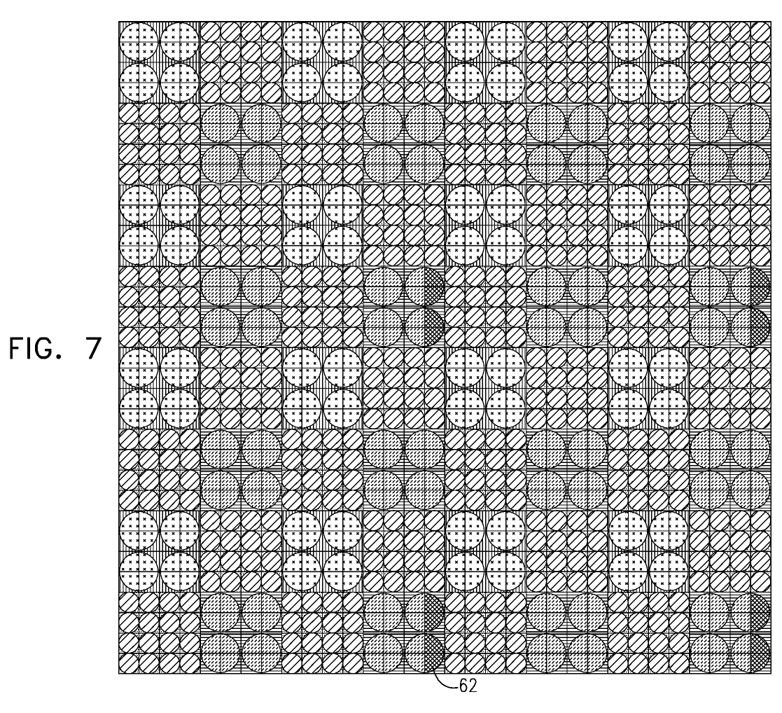

FIGS. 6 and 7 are schematic partial frontal view of image sensing device 22, showing still further possible configurations of color filters and microlenses in accordance with alternative embodiments of the invention. In the embodiment of FIG. 6, the red and blue regions of the color filter layer are covered by 1x2 OCLs, as in the embodiment of FIG. 2; whereas in the embodiment of FIG. 7, the red and blue regions are covered by 2x2 OCLs, as in the embodiment of FIG. 3. Within some of the red regions, however, the color filter layer comprises filters 60 or 62 of a color other than red over some of the photodetectors that are located under the 1x2 or 2x2 OCLs. Alternatively or additionally, the blue regions may include filters of a different color.

Filters 60 and 62 may be of a variety of different colors, depending on application requirements. For example, filters 60 and 62 may be green, to improve the resolution of the green color channel. Alternatively, filters 60 and 62 may be clear or grey (neutral density) to improve both the resolution and the spectral sensing range of the device. A metal shield or grid may be formed over the red or blue photodetectors in these groups to provide PDAF information. This sort of shield or grid is useful particularly in preserving PDAF information when the photodetector outputs in the arrays of FIGS. 6 and 7 are summed in 4x4 groups.

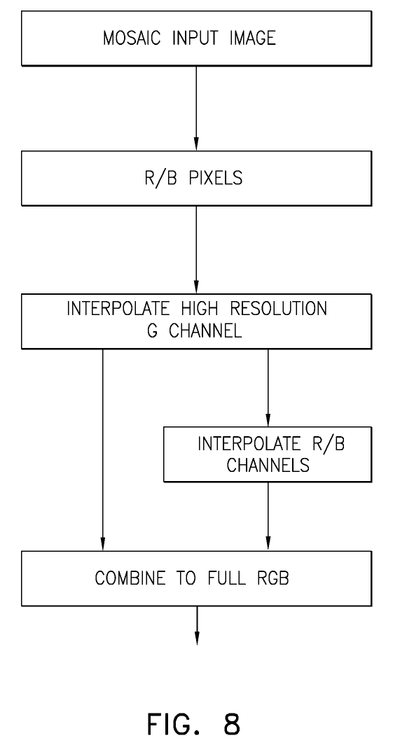

FIG. 8 is a flow chart that schematically illustrates a method for processing a mosaic image output by image sensing device 22, in accordance with an embodiment of the invention. Controller 28 (FIG. 1) applies this method in reconstructing a full-color RGB image based on signals output by photodetectors 34 in the red, green, and blue regions shown in the preceding figures, which are captured as a mosaic input image.

In the red and blue regions, at least some of the photodetectors share common microlenses for purposes of autofocus. Controller 28 sums the signals output by each such group of two or four photodetectors to compute an extended pixel value. The control computes a high- resolution green image by interpolating the signals of the photodetectors in the green regions over the red and blue regions. The controller then computes red and blue images by interpolating the pixel values of the photodetectors in the red and blue regions (including the summed autofocus groups), using the green image to furnish missing detail. The controller then combines the green, red, and blue images to provide the full RGB output.

In an alternative embodiment, a neural network may be trained to convert the raw mosaic input to a full RGB output, without explicitly performing the interpolation steps described above.

Although the embodiments described above include particular types and distributions of microlenses over the red and blue regions of an image sensing device, the principles of these embodiments may be applied in creating other microlens patterns, in accordance with the principles of the present invention. It will thus be understood that the embodiments described above are cited by way of example, and the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An image sensing device, comprising:
a semiconductor substrate;
a first array of photodetectors disposed on the substrate at a predefined pitch;
a color filter layer disposed over the photodetectors and comprising a matrix of red, green, and blue regions, each region overlying a respective group of the photodetectors; and
a second array of microlenses disposed over the color filter layer and comprising:
first microlenses having a first transverse dimension no greater than the pitch disposed respectively over all the photodetectors within the green regions; and
second microlenses having a second transverse dimension greater than the pitch disposed over at least some of the photodetectors within the red and blue regions, each second microlens being configured to focus light onto two or more of the photodetectors in the respective group.

2. The device according to claim 1, wherein the two or more of the photodetectors onto which the second microlenses focus the light define phase detection autofocus (PDAF) pixels.

3. Imaging apparatus, comprising: the device according to claim 2;
objective optics configured to image a target onto the device;
an autofocus mechanism configured to adjust a focal property of the objective optics; and
a controller configured to drive the autofocus mechanism responsively to signals output by the PDAF pixels.

4. The apparatus according to claim 3, wherein the controller is further configured to reconstruct a full- color image based on signals output by the photodetectors by first computing a green image by interpolating the signals of the photodetectors in the green regions over the red and blue regions and then computing red and blue images by interpolating the signals of the photodetectors in the red and blue regions using the green image.

5. The device according to claim 1, wherein the second transverse dimension is twice the pitch.

6. The device according to claim 5, wherein each of at least some of the second microlenses is configured to focus the light onto a respective 1x2 set of the photodetectors.

7. The device according to claim 6, wherein for some of the second microlenses, the respective 1x2 set of the photodetectors is disposed along a row of the array, while for others of the second microlenses, the respective 1x2 set of the photodetectors is disposed along a column of the array.

8. The device according to claim 5, wherein each of at least some of the second microlenses is configured to focus the light onto a respective 2x2 set of the photodetectors.

9. The device according to claim 1, wherein the second microlenses are disposed over all the photodetectors within the red and blue regions.

10. The device according to claim 1, wherein the second microlenses are disposed over only a first subset of the photodetectors within the red and blue regions, while the first microlenses are also disposed over a second subset of the photodetectors within the red and blue regions.

11. The device according to claim 1, wherein the respective group of the photodetectors that is overlain by each of the red, green, and blue regions comprises a 4x4 set of the photodetectors.

12. The device according to claim 1, wherein within one or more of the red or blue regions, the color filter layer comprises filters over some of the photodetectors of a color other than red or blue.

13. A method for imaging, comprising:
providing a first array of photodetectors on a substrate at a predefined pitch;
depositing over the photodetectors a color filter layer comprising a matrix of red, green, and blue regions, each region overlying a respective group of the photodetectors; and
forming over the color filter layer a second array of microlenses comprising:
first microlenses having a first transverse dimension no greater than the pitch disposed respectively over all the photodetectors within the green regions; and
second microlenses having a second transverse dimension greater than the pitch disposed over at least some of the photodetectors within the red and blue regions, each second microlens being configured to focus light onto two or more of the photodetectors in the respective group.

14. The method according to claim 13, wherein the two or more of the photodetectors onto which the second microlenses focus the light define phase detection autofocus (PDAF) pixels.

15. The method according to claim 14, and comprising:
imaging a target onto the photodetectors in the first array using objective optics; and
driving an autofocus mechanism to adjust a focal property of the objective optics responsively to signals output by the PDAF pixels.

16. The method according to claim 15, and comprising reconstructing a full-color image based on signals output by the photodetectors by first computing a green image by interpolating the signals of the photodetectors in the green regions over the red and blue regions and then computing red and blue images by interpolating the signals of the photodetectors in the red and blue regions using the green image.

17. The method according to claim 13, wherein the second transverse dimension is twice the pitch.

18. The method according to claim 13, wherein the second microlenses are disposed over all the photodetectors within the red and blue regions.

19. The method according to claim 13, wherein the second microlenses are disposed over only a first subset of the photodetectors within the red and blue regions, while the first microlenses are also disposed over a second subset of the photodetectors within the red and blue regions.

20. The method according to claim 13, wherein within one or more of the red or blue regions, the color filter layer comprises filters over some of the photodetectors of a color other than red or blue.
